(19) United States
(12) Patent Application Publication
(10) Pub. No.: US 2023/0152390 A1
(43) Pub. Date: May 18, 2023

(54) Method for Detecting Soft Shorts, Test Stand and Production Line

(71) Applicant: Bayerische Motoren Werke Aktiengesellschaft, Muenchen (DE)

(72) Inventors: Martin GOUVERNEUR, Berlin (DE); Thomas WOEHRLE, Muenchen (DE)

(21) Appl. No.: 17/920,512

(22) PCT Filed: May 5, 2021
(86) PCT No.: PCT/EP2021/061851

§ 371 Date: Oct. 21, 2022

(30) Foreign Application Priority Data
May 12, 2020 (DE) 10 2020 112 801.0

(51) Int. Cl. G01R 31/52; G01R 27/16; H01M 10/42; H01M 50/44; H01M 50/414; H01M 50/489; H01M 10/04

(52) U.S. Cl. CPC G01R 31/52; G01R 27/16; H01M 10/4285; H01M 50/44; H01M 50/414; H01M 50/489; H01M 10/0404

(57) ABSTRACT

A method for detecting soft shorts in an electrode assembly includes the following steps. First, the electrode assembly having at least one anode and at least one cathode is provided, a separator having an open porosity being inserted between each anode and cathode. Subsequently, the impedance of the electrode assembly is measured and the measured impedance is compared with a reference value. A soft short is detected if the measured impedance deviates from the reference value. The electrode assembly is not laminated, and the impedance is measured prior to the introduction of electrolyte and the installation of the electrode assembly in a galvanic cell are provided. A test stand for the method and a production line using the test stand are disclosed.

### BACKGROUND AND SUMMARY

The invention relates to a method for detecting soft shorts in an electrode assembly, to a test stand, and to a production line.

In the following, the term “lithium ion battery” is used synonymously for all terms for lithium-containing galvanic elements and cells commonly used in the prior art, such as, for example, lithium battery, lithium cell, lithium ion cell, lithium polymer cell, lithium ion battery cell, and lithium ion accumulator. In particular, rechargeable batteries (secondary batteries) are included. The terms “battery” and “electrochemical cell” are also used synonymously with the terms “lithium ion battery” and “lithium ion cell.” The lithium ion battery can also be a solid-state battery, for example, a ceramic or polymer-based solid-state battery.

Electrode assemblies are sequences of at least two different electrodes, at least one positive electrode (cathode) and at least one negative electrode (anode). Each of these electrodes includes at least one active material, optionally together with additives, such as electrode binders and additives for promoting conductivity.

A separator for electrical and mechanical insulation is arranged between each cathode and anode. However, the separator is permeable to ions, for example, to lithium ions in the case of a separator of a lithium ion battery.

In order to manufacture galvanic elements, for example, lithium ion batteries, the electrode assemblies and separators are subsequently packed into a housing, which is filled with electrolyte. Due to the presence of the electrolyte, ions can pass through the separator during the charging and the discharging of the galvanic element.

A general description of the lithium ion technology is found in chapter 9 (Lithium-Ionen-Zelle, author Thomas Wöhrle) of the “Handbuchs Lithium-Ionen-Batterien” (editor Reiner Korthauer, Springer, 2013) and in chapter 9 (Lithium-ion cell, author Thomas Wöhrle) of the book “Lithium-ion Batteries: Basics and Applications” (editor Reiner Korthauer, Springer, 2018).

During the manufacture of the galvanic element, it must be ensured that the at least one cathode and the at least one anode reliably remain separated from one another by the separator or the separators. If the separator is damaged or incorrectly aligned, a so-called soft short can occur, i.e., an internal short circuit between the cathode and the anode. In this case, the galvanic element is not operational and must be discarded.

In the prior art, the so-called “HiPot test” is used to detect soft shorts of this type. In the HiPot test, very high voltages of approximately 500 volts are applied at the electrodes of the electrode/separator assembly or galvanic cell to be tested. If the separator does not provide sufficient insulation, for example, due to a shifted arrangement or due to mechanical damage of the separator, a current flow arises at these very high voltages despite the separator and can be detected. This is also referred to as dielectric breakdown. In this case, it can be assumed that the galvanic cell is damaged. If the HiPot test is not passed, the electrode/separator assemblies are not further processed and are discarded.

In modern galvanic elements, in particular in lithium ion batteries, so-called “non-woven” separators are being used to an increasing extent. Such separators include a non-woven having at least open porosity. This is understood to mean that the separator at least partially has pores, which extend along a single axis across the entire thickness of the separator. Correspondingly, an angled or labyrinth pore structure is present only to a small extent, at least not exclusively. Such non-woven separators are commercially available and are formed from chemically, mechanically, and electrochemically highly stable fibers, for example, from polyester (DE 10 2009 0026 80 A1) or polyamide (U.S. Pat. No. 7,112,389 B1).

It has been shown that, upon utilization of such separators having open porosity, a soft short is detected in many cases upon application of the conventional HiPot test, even if the separator has not been damaged and is correctly arranged. There is a need, therefore, for alternative test methods in which a soft short can be reliably detected also upon utilization of stable separators having open porosity.

DE 102 07 070 A1 describes a method for manufacturing galvanic elements, in which individual cells, from which cell stacks for the galvanic element are to be formed, are initially tested, as the smallest unit, by means of an impedance measurement. A nondestructive 100% check is possible. Laminated cells are used as individual cells in this check. In laminated cells of this type, which are known, for example, from EP 1 261 048 B1, the individual integral parts, i.e., the electrode, the current collector, and the separator, are fixedly and permanently connected to each other, for example, by means of a plastic, and cannot be nondestructively separated. The method presented here demonstrates the possibility of carrying out impedance measurements also without electrolyte, since a sufficient contacting of the electrodes and the separators is achieved, due to residue from the lamination process, in order to make a finite impedance measurable. However, the method is therefore suitable only for laminated cells and electrode/separator stacks made up of multiple laminated cells. Electrode coils cannot be manufactured from such laminated cells without risking damage.

The problem addressed by the invention is to provide another possibility for reliably detecting soft shorts in electrode assemblies.

The problem is solved according to the invention using a method for detecting soft shorts in an electrode assembly, the method including the following steps: First, the electrode assembly having at least one anode and at least one cathode is provided, a separator having an open porosity being inserted between each anode and cathode. Subsequently, the impedance of the electrode assembly is measured and the measured impedance is compared with a reference value. A soft short is detected if the measured impedance deviates from the reference value. The electrode assembly is not laminated, and the impedance is measured prior to the introduction of electrolyte and the installation of the electrode assembly in a galvanic element.

According to the invention, no laminated electrodes or laminated cells are used. In other words, neither the anode, the cathode, nor the separator are fixedly connected to one another, but rather lie loosely on top of one another. It is therefore ensured that the components will be held together, in particular exclusively, by static friction of the individual integral parts of the electrode assembly.

The inventors have recognized that a finite impedance can be measured even in this case prior to the installation of the electrode assembly into a galvanic element and, in particular, prior to the introduction of electrolyte, whereby a soft short of the electrode assembly can be reliably detected. This is quite surprising, as gaps and air inclusions can be present due to the absence of a connection between the electrodes and the separators, the gaps and air inclusions generating very high interfacial resistances and, thus, infinite and, therefore, non-measurable values of the impedance are to be expected. In addition, no residue of lamination processes is present, for example, residual moisture, which should induce an appropriate conductivity.

A secondary positive aspect of the present invention is the fact that non-woven separators can also be reliably tested for a soft short and released in unlaminated assemblies. As a result, a lamination of non-woven separators does not necessarily need to be carried out for a soft short test, the non-woven separators often disadvantageously being adversely affected by the lamination process, in particular, due to the effect of high pressure and temperature.

The open porosity of the at least one separator makes it possible, however, to measure a finite impedance in this case as well. The inventors have recognized that the incomplete electrical insulation of such separators, unlike in the conventional HiPoT test, can be advantageously utilized in an impedance measurement under measuring conditions. Only lower voltages than for a HiPot test are necessary for an impedance measurement, so that, in addition, the energy demand and, thus, the costs of the test method are reduced. In the conventional HiPot test, the incomplete electrical insulation by separators having open porosity results in a dielectric breakdown.

The reference value can be determined in advance on the basis of electrode assemblies that have a correct functionality. For example, the reference value is a mean value of the measured impedances of electrode assemblies having correct functionality that are measured in advance. The reference value can also be merely a lower limit or an upper limit of a known range of impedance values. In bilayer cells having an electrode surface area of approximately 1800 mm² and a thickness of approximately 500 μm, a reference value on the order of approximately 40 kΩ can be expected in a measurement using an AC voltage of approximately 1 kHz. Large-area PHEV1 coil cells having an electrode surface area of approximately 8000 cm² suggest a reference range from 80 mΩ to 120 mΩ.

According to the invention, a statistical evaluation of previous impedance measurements of known electrode assemblies can also be carried out to define a measuring range in which measured impedance values are situated in the case of functional electrode assemblies. In this variant, the reference value is a reference range.

According to the invention, the impedance is measured prior to the installation of the electrode assembly into a housing and, in particular, prior to the introduction of an electrolyte into the housing. In this way, the method according to the invention makes it possible to check the electrode assembly even before the electrode assembly is processed in further work steps. Therefore, faulty electrode assemblies and mechanical damage, for example, of the separator, can be detected early in the process and sorted out. As a result, the rejects in the manufacture of galvanic cells and, thus, the manufacturing costs of the galvanic cells, are reduced. Since slight internal soft shorts can also first become noticeable in use during the service life of the cell, the reliability of the cell is also increased.

The galvanic element is, in particular, a lithium ion battery.

In one variant, a soft short is detected only when the measured impedance deviates from the reference value by more than a predetermined tolerance range. For example, a deviation of up to ±15% from the reference value can be selected as the tolerance range.

The tolerance range, similarly to the reference value, can be ascertained by means of a previous measurement of the impedance at electrode assemblies having correct functionality. In particular, by means of the tolerance range, production-related fluctuations can be taken into account, the production-related fluctuations not yet negatively affecting the correct functionality of the electrode assembly to an excessive extent, however.

If the reference value is merely an upper limit or a lower limit, the tolerance range can be a deviation by a predefined percentage above the upper limit or below the lower limit, for example, a deviation of 5% above the upper limit or below the lower limit.

If the reference value is a mean value that was ascertained from a statistical analysis of previous measurements, the tolerance range can be a predefined multiple of the standard deviation of the measured values by the reference value. The at least one separator is, in particular, a non-woven or a paper. Preferably, the separator is, in particular, a “non-woven” separator. Such separators can be made from plastic fibers that were obtained by means of extrusion from polymer melts or by other known methods of fiber manufacture. Continuous fibers or staple fibers can be used as the fibers to form the non-wovens. Non-woven separators, which are formed at least partially from biopolymers, are known from DE 10 2014 205 234 A.

The non-wovens used as separators can be oriented or formed as entangled mesh. All known methods, in particular dry methods, aerodynamic methods such as meltblown methods and spunbond methods, wet methods, and extrusion methods, can be used for the manufacture of non-wovens. The non-wovens can be mechanically, chemically, or thermally solidified in a known manner. In particular, no complex further processing steps, for example, a structuring of the fibers, need to be carried out to manufacture non-woven separators from the plastic fibers. Non-woven separators can increase the mechanical, chemical, electrochemical, and thermal stability of the electrode assembly.

Moreover, the at least one separator can include fibers made of a plastic that is selected from the group made up of polyimide, polyester, aramid, copolymers, and mixtures thereof. Separators having fibers made of these plastics have a melting temperature and puncture resistance, which are increased as compared to polyethylene and polypropylene, as the result of which the temperature resistance and reliability of the separators are increased. In addition, these plastics can be extruded from polymer melts using known methods.

The separator has, in particular, a thickness in the range from 8 μm to 25 μm, preferably from 10 μm to 15 μm. Using such thin separators, high specific energies and energy densities can be achieved in galvanic elements that include an electrode assembly according to the invention. With respect to thin separators, it is particularly likely that a HiPot test displays false—positive soft shorts, so that, in this case, the method according to the invention can be used particularly advantageously as an alternative.

The method according to the invention can be applied on miniature pouch cells having an electrode surface area of 2 cm×4 cm and on large-area PHEV1 cells having an electrode surface area of up to 15 cm×480 cm (coil PHEV1 cell) or larger. The at least one cathode and the at least one anode, in one variant, can therefore have an electrode surface area of at least 800 mm², preferably at least 5000 mm², further preferably at least 7000 mm², at least 8000 mm² or at least 10000 mm².

Exemplary electrode surface areas are in the range from 800 mm² to 800000 mm², in particular in the range from 5000 mm² to 20000 mm² or from 7200 mm² to 16200 mm². Therefore, the electrodes of the electrode assembly can be comparatively large-area electrodes. The method according to the invention is also suited for such electrode surface areas.

Exemplary dimensions of the electrodes are in the range from 100 mm×50 mm to 200 mm×100 mm, in particular from 120 mm×60 mm to 180 mm×90 mm.

The electrode assembly includes, in particular, at least 5 anodes and at least 5 cathodes, preferably at least 8 anodes and at least 8 cathodes. In other words, the method according to the invention can also be used specifically for electrode assemblies having a large number of individual electrodes, none of which has yet been fixedly connected to another and/or saturated with an electrolyte. As a result, it becomes possible to at least partially separate the electrode assemblies, which are still loosely connected, again if a soft short is detected by means of the method according to the invention. In this way, the faulty cathode or anode and/or the faulty separator can be identified, while the other integral parts of the electrode assembly can be reused.

In one further variant, which is preferably used for the mass production of lithium batteries, each individual bilayer cell made up of precisely one cathode and one anode and having precisely one separator can be tested with the method according to the invention before the bilayer cells are combined to form a stack. Bilayer cells identified as faulty can be sorted out and discarded.

Moreover, the galvanic element can be a cell stack or a cell coil. Since, according to the invention, the individual electrodes of the electrode assembly have not yet been connected to one another, in particular, no laminated individual cells are used, the method according to the invention can be used not only for cell stacks, but also for cell coils. Therefore, in contrast to the use of laminated individual cells, cell coils can also be reliably checked by means of impedance measurement.

The measurement of the impedance can be carried out using an AC current or an AC voltage having a frequency in the range from 500 Hz to 1.5 kHz, in particular having a frequency of 1 kHz. At these frequencies, a short measuring time as well as a high reliability of the impedance measurement can be achieved.

The real part and the imaginary part of the impedance and/or the absolute value of the impedance can be used for the measurement of the impedance. In other words, a phase-sensitive value and/or an absolute value of the impedance can be used.

The problem addressed by the invention is also solved by a test stand for checking an electrode assembly, the test stand being configured for carrying out the above-described method.

The test stand can be integrated, in particular, into a production line for manufacturing galvanic elements, for example, into a formation system.

In particular, the test stand includes a sensor module having contacts for contacting conductor lugs of the electrode assembly.

Moreover, the test stand can include a memory module and an evaluation module. The memory module can store a history of measured impedance values in order to be able to carry out a statistical evaluation on the basis of the stored values, for example, to determine a reference range for the impedance measurement. The reference value as well as the tolerance range can also be stored in the memory module. The evaluation module can compare the impedance measured by the sensor module with the reference value.

Additionally, the test stand can include a communication module, which is configured for exchanging data with further integral parts of the production line. Therefore, detected soft shorts can be reported to further devices of the production line, which can subsequently sort out or further process faulty electrode assemblies.

The invention is solved, furthermore, by a production line including a test stand of the above-described type.

Further advantages and properties of the invention result from the following description of exemplary embodiments, which are not to be understood to be limiting, and the drawings.

### BRIEF DESCRIPTION OF THE DRAWINGS

FIG. 1 schematically shows a test stand according to an embodiment of the invention in a production line according to an embodiment of the invention; and

FIG. 2 shows a block diagram of a method according to an embodiment of the invention.

### DETAILED DESCRIPTION OF THE DRAWINGS

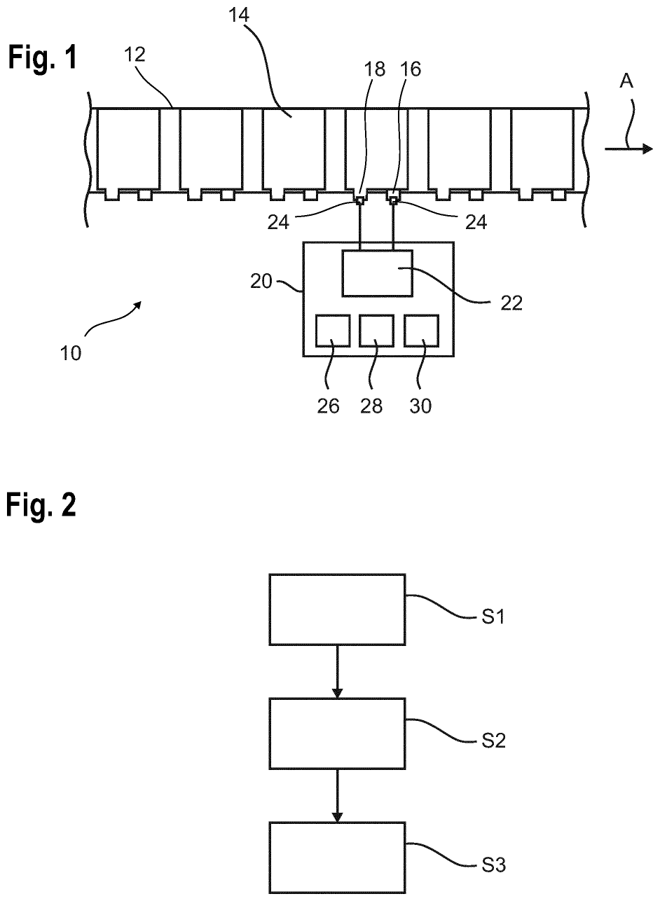

FIG. 1 shows a section of a production line 10 for manufacturing galvanic elements.

The production line 10 includes a conveyor belt 12, on which a plurality of electrode assemblies 14 is located.

The electrode assemblies 14 include, arranged loosely on top of one another, at least one anode, at least one cathode, and a separator between each anode and cathode, the electrode assembly 14 containing the same number of cathodes and anodes.

In the embodiment shown, each of the electrode assemblies 14 includes at least 50 cathodes and at least 50 anodes, preferably at least 80 cathodes and at least 80 anodes, which, as a cell stack, form the electrode assembly 14. In principle, the electrode assemblies 14 could also be cell coils, however.

Each electrode assembly 14 has a cathode current collector lug 16 and an anode current collector lug 18. The cathode current collector lug 16 and the anode current collector lug 18 are each designed as a collecting member of individual current collectors of the cathodes and anodes, respectively, so that all cathodes of the particular electrode assembly 14 can be electrically contacted via the cathode current collector lug 16 and all anodes of the particular electrode assembly 14 can be electrically contacted via the anode current collector lug 18.

Each of cathodes and the anodes include at least one active material.

In principle, all materials known from the prior art can be used for the cathode active material. These include, for example, LiCoO₂, lithium nickel cobalt manganese compounds (known by the abbreviation NCM or NMC), lithium nickel cobalt aluminum oxide (NCA), lithium iron phosphate, and other olivine compounds as well as lithium manganese oxide spinel (LMO). So-called over-lithiated layered oxides (OLO) can also be used.

The cathode active material can also contain mixtures of two or more of the aforementioned lithium-containing compounds.

In the embodiment shown, the cathode active material is NMC622 (LiNi_{0.6}Mn_{0.2}Co_{0.2}O₂).

Additionally, the cathode active material can include further additives, for example, carbon or carbonaceous compounds, in particular conductive carbon black, graphite, carbon nano tubes (CNT), and/or graphene. Such additives can be utilized as conductivity modifiers to increase the electrical conductivity within the electrode.

Moreover, the cathode can include a binding agent (electrode binder), which holds the active material and, if necessary, the conductive material (such as conductive carbon black) together and also binds these to the collector foil. The electrode binder can be selected from the group made up of polyvinylidene fluoride (PVdF), polyvinylidene fluoride hexafluoropropylene copolymer (PVdF-HFP), polyethylene oxide (PEO), polytetrafluoroethylene (PTFE), polyacrylate, styrene butadiene rubber (SBR), polyvinylpyrrolidone (PVP), carboxymethylcellulose (CMC), and mixtures and copolymers thereof.

The anode active material can be selected from the group made up of lithium metal oxides, such as, for example, lithium titanium oxide, metal oxides, such as Fe₂O₃, ZnO, ZnFe₂O₄, carbonaceous materials, such as, for example, graphite, synthetic graphite, natural graphite, graphene, mesocarbon, doped carbon, hard carbon, soft carbon, fullerenes, mixtures of silicon and carbon, silicon, silicon suboxide (“SiO”), silicon alloys, lithium alloys, and mixtures thereof. A pure lithium anode is also possible.

Niobium pentoxide, tin alloys, titanium dioxide, titanates, tin dioxide, and silicon can also be used as electrode material for the negative electrode.

In the embodiment shown, graphite is the anode active material.

In addition to the anode active material, the anode can include further components and additives, such as, for example, a substrate, a binding agent, or conductivity enhancers. All typical compounds and materials known from the prior art can be used as further components and additives.

The separators are “non-woven” separators having open porosity and can include fibers made of a plastic, which is selected from the group made up of polyimide, polyester, aramid, copolymers, and mixtures thereof.

In the embodiment shown, the separator is a non-woven formed from polyester fibers.

The production line 10, furthermore, includes a test stand 20 according to the invention for checking the electrode assemblies 14.

The test stand 20 includes a sensor module 22, which, by means of contacts 24, can electrically contact the cathode current collector lug 16 and the anode current collector lug 18 of an electrode assembly 14 to be tested and carry out an impedance measurement.

The test stand 20 also includes a memory module 26, an evaluation module 28, and a communication module 30.

A method according to the invention for detecting soft shorts in the electrode assemblies 14 is described in the following.

First, the electrode assemblies 14 are provided (step S1 in FIG. 2).

The conveyor belt 12 is configured for moving the electrode assemblies 14 arranged on the conveyor belt 12 in the direction indicated with an arrow A in FIG. 1.

Therefore, each of the electrode assemblies 14 is guided, one after the other, at the level of the above-described test stand 20, so that the cathode current collector lug 16 and the anode current collector lug 18 of the electrode assembly can be electrically contacted by means of the contacts 24 of the sensor module 22.

Thereafter, the sensor module 22 carries out an impedance measurement of the electrode assembly using an AC current having a frequency of 1 kHz (step S2 in FIG. 2).

The measured value is transmitted from the sensor module 22 to the memory module 26 in which a previously established reference value is also stored.

Subsequently, the evaluation module 28 compares the measured value stored in the memory module 26 with the reference value. If the measured value deviates from the reference value by more than a previously established tolerance range, which is also stored in the memory module 26, a soft short of the electrode assembly 14 is detected in the embodiment shown (step S3 in FIG. 2).

If this is the case, the test stand 20 can communicate by means of the communication module 30 with further (not represented) devices of the production line 10 that sort out the faulty electrode assembly 14. For this purpose, the communication module 30 can be configured for wireless and/or hard-wired communication with the further devices of the production line 10.

Table 1 shows a comparison of the impedance measurement according to the invention with the conventional “HiPot” test. The electrode assemblies, each having one cathode, one anode, and one separator, are compared.

The electrode assemblies are measured by means of both test methods before the initial charging in a galvanic element.

In the HiPoT test, a high voltage of 500 V is applied at the electrode assembly. If a current flow is subsequently detected, the corresponding electrode assembly is classified as faulty.

As is apparent in table 1, in the case of the HiPoT test, all ten electrode assemblies are classified as faulty prior to the introduction of electrolyte and formation, while the same electrode assemblies are identified by the method according to the invention as functional by means of an impedance measurement.

After the electrode assembly had been installed in a housing of a galvanic element, electrolyte had been introduced, and the galvanic element had been formed, the correct functionality of the electrode assembly was confirmed in every case.

The method according to the invention, by utilizing a separator having open porosity, therefore permits an earlier and simultaneously reliable detection of soft shorts than is possible using the conventional HiPoT test.

TABLE 1
Comparison of HiPoT impedance measurement and impedance
measurement according to the invention.

| | | Method according to the |
|---|---|---|
| Test method | HiPoT | invention |
| Cell structure | Cathode: NMC622 | Cathode: NMC622 |
| | Anode: Graphite | Anode: Graphite |
| | Separator: Polyester, | Separator: Polyester, |
| | non-woven | non-woven |
| Number | 10 | 10 |
| Soft short detection | 10/10 | 0/10 |
| prior to formation | | |

The galvanic elements manufactured with the tested electrode assemblies were checked, after formation and a service life of 14 days, to determine whether the cell voltage was further reduced as compared to the anticipated self-discharge. None of the cells that had been previously checked using the method according to the invention exhibited a voltage drop and, thereby, all the cells exhibited a correct mode of operation.

1.-11. (canceled)

12. A method for detecting a soft short in an electrode assembly, comprising:
providing the electrode assembly having at least one anode and at least one cathode, a separator having an open porosity being between each anode and cathode;
measuring an impedance of the electrode assembly; and
comparing the measured impedance with a reference value;
wherein the electrode assembly is not laminated, and the impedance is measured prior to introduction of electrolyte and installation of the electrode assembly into a galvanic element.

13. The method according to claim 12, wherein
a soft short is detected when the measured impedance deviates from the reference value by more than a predetermined tolerance range.

14. The method according to claim 12, wherein
the separator is a non-woven, and
the separator includes fibers formed from a plastic that is selected from the group consisting of: polyimide, polyester, aramid, copolymers, and mixtures thereof.

15. The method according to claim 12, wherein
the separator has a thickness in a range from 8 μm to 25 m.

16. The method according to claim 12, wherein
the separator has a thickness in a range from 10 μm to 15 μm.

17. The method according to claim 12, wherein
the at least one cathode and the at least one anode have an electrode surface area of at least 800 mm².

18. The method according to claim 12, wherein
the at least one cathode and the at least one anode have an electrode surface area of at least 5000 mm².

19. The method according to claim 12, wherein
the at least one cathode and the at least one anode have an electrode surface area of at least 7000 mm².

20. The method according to claim 12, wherein
the at least one cathode and the at least one anode have an electrode surface area of at least 8000 mm².

21. The method according to claim 12, wherein
the at least one cathode and the at least one anode have an electrode surface area of at least 10000 mm².

22. The method according to claim 17, wherein the electrode surface area is in a range from 800 mm² to 800000 mm².

23. The method according to claim 17, wherein the electrode surface area is in a range from 5000 mm² to 20000 mm².

24. The method according to claim 17, wherein the electrode surface area is in a range from 7200 mm² to 16200 mm².

25. The method according to claim 12, wherein
the electrode assembly has precisely one cathode and one anode having precisely one separator, or
the electrode assembly has at least 5 anodes and at least 5 cathodes.

26. The method according to claim 12, wherein
the electrode assembly is a cell stack or a cell coil.

27. The method according to claim 17, wherein
an AC current or an AC voltage having a frequency in the range from 500 Hz to 1.5 kHz is used for measuring the impedance.

28. The method according to claim 17, wherein
the AC frequency is 1 kHz.

29. A test stand for checking an electrode assembly, comprising:
a processor and associated memory operatively configured to:
measure an impedance of the electrode assembly, the electrode assembly having at least one anode and at least one cathode, and a separator having an open porosity between each anode and cathode; and
compare the measured impedance with a reference value;
wherein the electrode assembly is not laminated, and the impedance is measured prior to introduction of electrolyte and installation of the electrode assembly into a galvanic element.

30. A production line, comprising:
the production line for galvanic elements that include an electrode assembly; and
a test stand according to claim 29.
